(19) United States
(12) Patent Application Publication
(10) Pub. No.: US 2022/0244303 A1
(43) Pub. Date: Aug. 4, 2022

(54) METHOD FOR ASCERTAINING AND DEPICTING POTENTIAL DAMAGED AREAS ON COMPONENTS OF OVERHEAD CABLES

(71) Applicant: Siemens Energy Global GmbH & Co. KG, Munich, Bayern (DE)

(72) Inventors: Josef Alois Birchbauer, Seiersberg (AT); Christoph Hobmaier, Wien (AT); Simon Hochstöger, Wien (AT); Olaf Kähler, Graz (AT); Stefan Wakolbinger, Graz (AT)

(73) Assignee: Siemens Energy Global GmbH & Co. KG, Munich, Bayern (DE)

(21) Appl. No.: 17/620,706

(22) PCT Filed: Jun. 22, 2020
(86) PCT No.: PCT/EP2020/067304

§ 371 Date: Dec. 19, 2021

(30) Foreign Application Priority Data
Jun. 27, 2019 (EP) 19182926.6

(51) Int. Cl. G01R 31/08

(52) U.S. Cl. CPC G01R 31/085; G01R 31/088

(57) ABSTRACT

A method for ascertaining and depicting potential damaged areas on objects of overhead cables, includes: the overhead cable and its surroundings are captured and a three-dimensional representation is created; relevant components and infrastructure elements are ascertained from the three-dimensional representation; components and infrastructure elements are examined for intactness; if potential damaged areas are detected, the position thereof is ascertained; depictions of the identified infrastructure elements having potential damaged areas with position statements are created.

### CROSS REFERENCE TO RELATED APPLICATIONS

This application is the US National Stage of International Application No. PCT/EP2020/067304 filed 22 Jun. 2020, and claims the benefit thereof. The International Application claims the benefit of European Application No. EP19182926 filed 27 Jun. 2019. All of the applications are incorporated by reference herein in their entirety.

### FIELD OF INVENTION

The invention relates to a method for ascertaining and depicting potential damaged areas on components of overhead cables.

### BACKGROUND OF INVENTION

Electrical overhead cables, the voltage-conducting lines of which are guided in the open through the air and are usually also only insulated from one another and from the ground by the surrounding air, are used, for example, as high-voltage and medium-voltage cables and also railway cables.

To avoid short-circuits or cable interruptions and electrical injuries possibly resulting therefrom, overhead cables have to maintain specific minimum distances from the ground, from buildings, but also from the surrounding vegetation.

To ensure this, regular inspections of these cables are prescribed.

Due to their dimensions of many kilometers in length and a height of approximately 60 meters, monitoring these overhead cables is a task which is typically carried out by means of helicopters or unmanned flying objects or also by on-site inspection.

The relevant terrain is flown over at a height free of obstructions for this purpose and, for example, photographed and/or scanned by means of LiDAR and the result is recorded as a three-dimensional data set and evaluated.

The results of the inspection processes are recorded as findings, from which measures, for example repairs, can subsequently be derived.

Providing these findings with graphic depictions is known, for example, the position of faulty components such as an insulator on a mast can be indicated by a symbol such as an arrow or a marking.

This visualization or the identification of the position of the finding generally takes place manually. The schematic drawings of the masts also either have to be derived from planning data or created manually.

Flying over high-voltage transmission cables or other systems by means of laser scanning devices, and/or image recording with subsequent visual checking by a trained technician has corresponded to routine practice for years.

In addition to recordings in the visible range of light, recordings in the near infrared range or using thermal infrared are also advantageous for certain applications. Near infrared having a wavelength of 780 nm to 3 μm (spectrum ranges IR-A and IR-B) is thus particularly well suitable for detecting vegetation, since chlorophyll has a higher reflectivity in the near infrared range by approximately a factor of 6 than in the visible spectrum. This effect can be utilized to recognize vegetation in that a recording is made in the advantageously red spectrum of the visible range, and a further recording is made in the near infrared. Utilitarian objects have an approximately equal reflectivity both in the visible and also in the near infrared range, while chlorophyll-containing vegetation has a significantly higher reflectivity in the near infrared. Thus, for example, even green utilitarian objects can be distinguished from vegetation which is also green.

However, thermal defects such as hot points can also be recognized using infrared recordings.

Recordings in the ultraviolet light range can also be expedient since, for example, corona effects/partial discharges are particularly clearly recognizable thereon.

The human factor is problematic here, i.e., errors occur due to negligence, for example because of fatigue or inexperience.

### SUMMARY OF INVENTION

The invention is based on an object of automating the visualization of findings.

This object is achieved according to the invention by a method according to the independent claim.

Advantageous embodiments result from the dependent claims.

In contrast to the manual locating of findings, the present invention provides locating the finding fully automatically and also generating a suitable visualization for easy finding of the finding for the inspection personnel fully automatically.

It is advantageous if, from a point cloud data set ascertained by means of a laser scanning device about the overhead cable and its surroundings, which also comprises the exact position for the individual points, infrastructure elements of the overhead cable such as masts, and components such as fittings and attachments are ascertained and depictions of these elements are analyzed for recognizable damage such as breaks, chipping, but also foreign bodies such as hanging ice or vegetation.

Methods of machine learning (artificial intelligence) known from the prior art are advantageously used for this purpose.

When potential damaged areas have been ascertained in such a way, their position is recorded and indicated in a depiction of the affected infrastructure element, for example, by means of an arrow or circular rings.

As part of the findings, these depictions enable the service personnel to carry out repairs efficiently and accurately.

### BRIEF DESCRIPTION OF THE DRAWINGS

The invention will be explained in more detail on the basis of figures, in which: FIGS. 1a, 1b, 1c and

FIGS. 2a, 2b show examples of depictions of masts of an overhead cable.

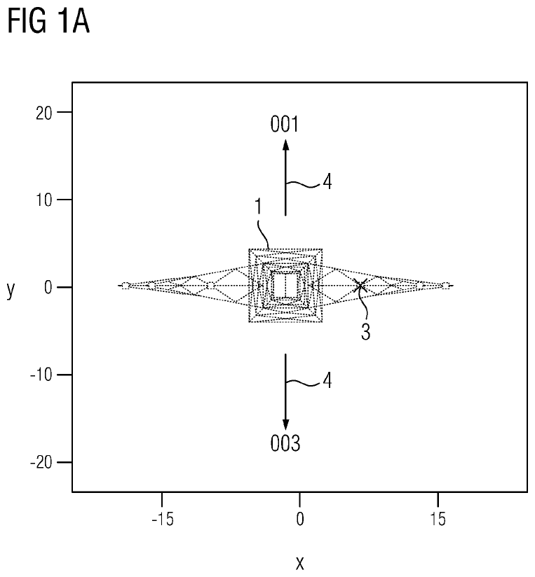

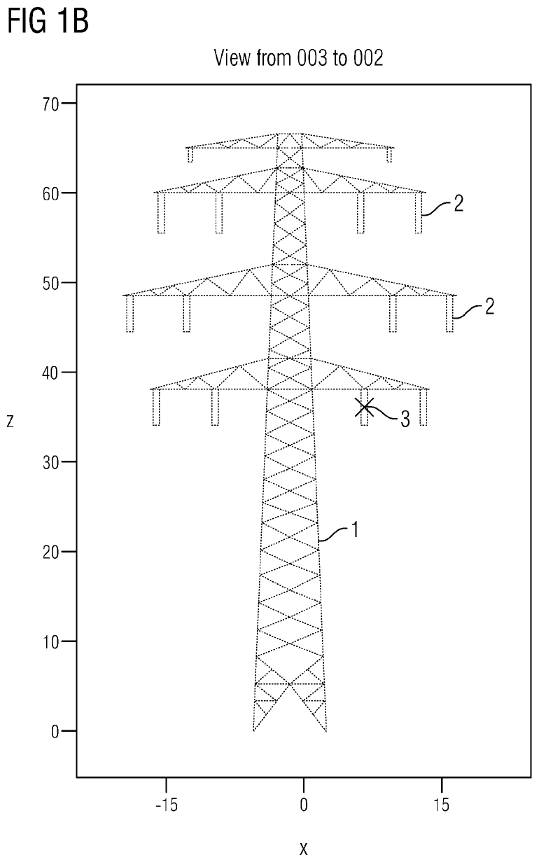

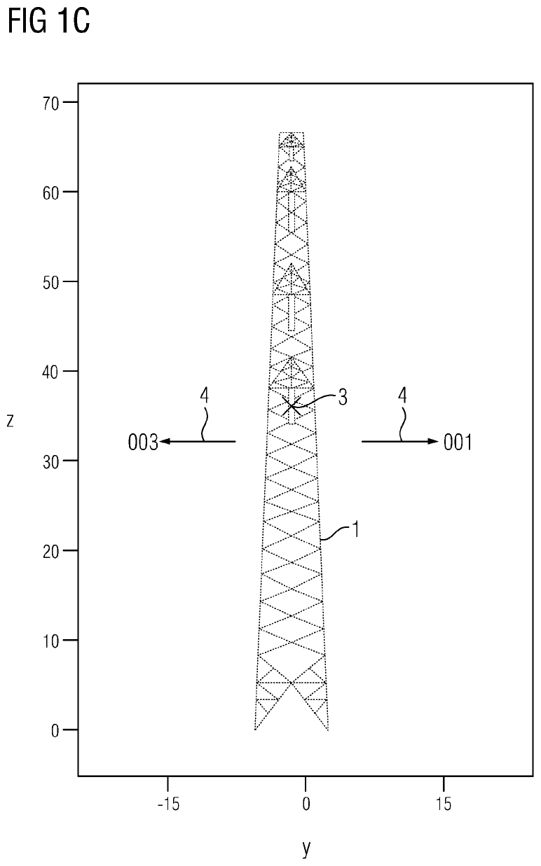

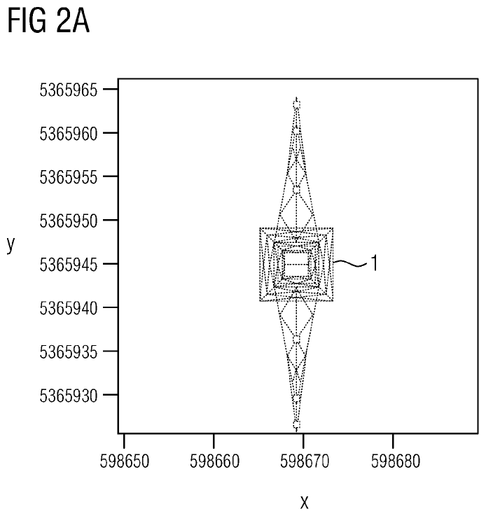

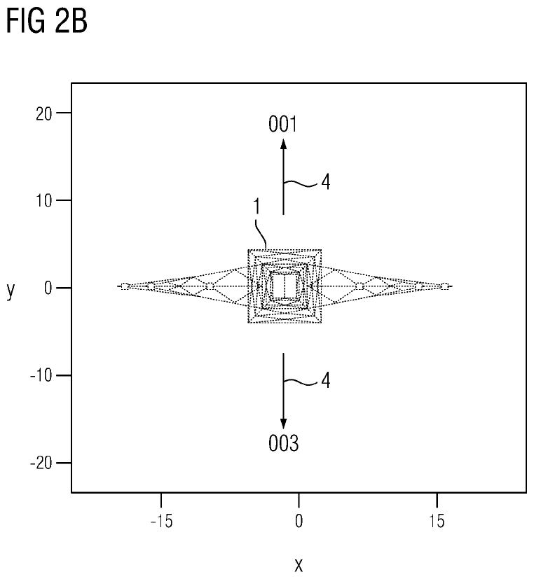

### DETAILED DESCRIPTION OF INVENTION

The illustrations contained in the figures of masts 1 of an overhead cable were derived from point cloud data sets for these masts ascertained by means of a laser scanning device (LIDAR).

LIDAR (light detection and ranging) refers to a method related to radar for optical distance and speed measurement and for remote measurement of atmospheric parameters. Instead of radio waves as in radar, laser beams are used.

During use as a laser scanner, light pulses are emitted, which are reflected from object points. The object point has to be visible at least from one direction in this case. The requirement is diffuse reflection at the surface. The technology functions independently of sunlight and enables large amounts of 3D information to be obtained about the objects at very fast recording rates.

The laser measures distance values of the scanner to objects in the surroundings in each case, so that a point cloud data set results from a plurality of measurements. If the position of the laser scanner or of the carrier vehicle, typically of a flying object such as a drone, a fixed wing aircraft, or a helicopter, is known, the position of a point from the point cloud data set can thus be reconstructed very accurately by reference to the position of the laser scanning device or the flying object and the direction on which the laser scanning device is aligned. In dynamic measuring methods, for example, mobile laser scanning or airborne laser scanning, laser scanners are used jointly with a GNSS/INS system (global navigation satellite system or inertial navigation system, respectively).

If the relative orientation between the GNSS/INS system and the laser scanner is known, a 3D point cloud can be generated by combining the vehicle trajectory and the laser scanning measurements (distance and directions).

The individual points of the 3D point cloud or the corresponding point cloud data set are classified with respect to their association with certain elements of the overhead cable and its surroundings, i.e., it is established whether the point is, for example, part of a mast 1, of a line, or of an insulator 2, or whether it can be assigned to the surroundings.

This is carried out on the basis of the relationship of the points with its surroundings using methods of machine learning, in which the class assignment of the points is learned from predefined training data on typical patterns of components such as insulators, mast elements, etc.

These recognized components are inspected for possible damaged areas such as breaks, cracks, ice, vegetation and the position of the ascertained potential damaged areas or sources of error are recorded.

The inspection of the components for damaged areas or for integrity is carried out in the exemplary embodiment on the basis of the point cloud data set, but can similarly be carried out on depictions derived therefrom or independent items of information, for example, sensor data, images, observations, etc.

Two-dimensional standardized views such as ground plan, vertical plan, and top plan are derived using suitable transformations for the infrastructure elements identified therefrom, thus, for example, the overhead cable mast, on which the components are arranged as so-called fittings or attachments.

It is particularly advantageous here if only the identified infrastructure elements 1 and their immediate surroundings are transformed into a two-dimensional view and thus the computing effort is kept low and the speed of the transformation can be increased.

So-called principal component analysis is advantageously applied here.

Principal component analysis, the underlying mathematical method of which is also known as principal axis transformation or singular value decomposition, or principal component analysis, is a method of multivariate statistics. It is used to structure, simplify, and illustrate extensive data sets in that a plurality of statistical variables is approximated by a smaller number of linear combinations which are as informative as possible (the “principal components”).

According to the invention, the transformation parameters ascertained once for an infrastructure element such as a mast 1 are recorded and can then be applied in the same manner thereafter to all fittings and attachments of this infrastructure element 1, for example, insulators 2.

In one finding, the damaged areas 3 and the affected infrastructure elements 1 are depicted graphically, wherein the position of a potential damaged area 3 on an element can be indicated, for example, by means of an arrow or circle.

This graphic depiction can additionally comprise additional orientation specifications 4, for example, compass directions or indications of the underlying viewing direction of a depiction “view from mast 2 to mast 3”, to thus further simplify the finding of the potential damaged areas.

In the exemplary embodiment, the overhead cable is acquired by means of a laser scanner. However, it is also possible to obtain three-dimensional representations from two-dimensional image recordings by means of photogrammetric methods and use these as the basis of the further evaluation.

### LIST OF REFERENCE NUMERALS

1 overhead cable mast
2 insulator
3 potential damaged area
4 orientation specifications

1. A method for ascertaining and depicting potential damaged areas on components of overhead cables, the method comprising:
acquiring the overhead cable and its surroundings and creating a three-dimensional representation thereof;
ascertaining certain components and infrastructure elements of the overhead cable and its surroundings from the three-dimensional representation;
inspecting the ascertained components and infrastructure elements for integrity;
when potential damaged areas are recognized, ascertaining a position thereof;
creating depictions of infrastructure elements identified as having potential damaged areas with position specifications.

2. The method as claimed in claim 1,
wherein the overhead cable is acquired by a laser scanning device;
wherein positions are assigned to points of a point cloud data set from the position of the laser scanning device and its alignment, and
wherein a three-dimensional point cloud data set is created as the three-dimensional representation.

3. The method as claimed in claim 2,
wherein a classification of the points with respect to their association with certain infrastructure elements is carried out by an automatic classification method.

4. The method as claimed in claim 3,
wherein methods of machine learning are provided as the automatic classification method, in which class assignment of the points is learned from predefined training data.

5. The method as claimed in claim 1, further comprising:
transforming only the identified infrastructure elements and their immediate surroundings into a two-dimensional view, thereby lowering computing effort and increasing transformation speed.

6. The method as claimed in claim 5,
wherein the depictions of the identified infrastructure elements comprise standardized views.

7. The method as claimed in claim 1,
wherein the depictions of the identified infrastructure elements are derived by a transformation matrix from the three-dimensional representation.

8. The method as claimed in claim 7,
wherein parameters of the transformation matrix are determined by principal axis transformation.

9. The method as claimed in claim 1,
wherein recognized potential damaged areas are provided in the depictions of respectively affected infrastructure elements with markings.

10. The method as claimed in claim 1, further comprising:
generating additional orientation specifications from parameters of the transformation.

11. The method as claimed in claim 1,
wherein the acquisition of the overhead cable takes place from a flying object.

12. The method as claimed in claim 6,
wherein the standardized views comprise ground plan, vertical plan, and side plan.

13. The method as claimed in claim 9,
wherein the markings comprise arrows.
